(19) United States
(12) Patent Application Publication
(10) Pub. No.: US 2024/0056036 A1
(43) Pub. Date: Feb. 15, 2024

(54) TUNABLE MATCHING NETWORK FOR PUSHPULL POWER AMPLIFIER

(71) Applicant: Spreadtrum Communications USA Inc., San Jose, CA (US)

(72) Inventors: Jason X Deng, Greensboro, NC (US); Rattapon Lertpiriyapong, Colfax, NC (US)

(21) Appl. No.: 17/888,097

(22) Filed: Aug. 15, 2022

(51) Int. Cl. H03F 3/195; H03F 3/26; H03F 3/50

(52) U.S. Cl. CPC H03F 3/195; H03F 3/265; H03F 3/505

(57) ABSTRACT

A radio-frequency (RF) push-pull amplifier circuit that includes: a first transistor; a transformer; and a first matching circuit comprising at least one capacitor and at least one inductor, in which an input of the first matching circuit is coupled to an output of the first transistor, an output of the first matching circuit is coupled to an input of the transformer, and the first matching circuit is configured to transform an impedance at the input of the transformer into a first predefined impedance at the output of the first transistor.

### BACKGROUND

Radio frequency (RF) power amplifiers are used in modern digital telecommunications to amplify RF signals, e.g., for transmission to base stations and other devices. In a wireless terminal, such as a cellular phone, a RF power amplifier front end module amplifies a modulated RF signal from a transceiver baseband and sends the signal to an antenna for radiating out to a base station. To maintain high performance, RF power amplifiers are designed to reduce battery consumption and spurious emissions, while still achieving the required output power. Performance may be evaluated based on certain parameters, such as output power, gain, power added efficiency (PAE), linearity (e.g., adjacent cannel power ratio or error vector magnitude), and harmonics leakage, among other factors. The RF power amplifier performance may determine what mode (2G, 3G, 4G, 5G, and WiFi) the transceiver can support, how long the battery can last, and how stable the communication link is.

### SUMMARY

The subject matter disclosed herein covers a tunable matching network for a radio frequency (RF) amplifier front end circuitry. In particular, the subject matter covers a tunable matching network that can be combined with pushpull topology in the RF amplifier front end module. The tunable matching network allows designers to reduce undesirable impact of lead and/or trace wire inductance to allow improvements in amplifier performance and reduction in die size.

In general, in some aspects, the subject matter of the present disclosure can be embodied in a radio-frequency (RF) push-pull amplifier circuit, in which the RF amplifier circuit includes: a first transistor; a transformer; and a first matching circuit including at least one capacitor and at least one inductor. An input of the first matching circuit is coupled to an output of the first transistor, an output of the first matching circuit is coupled to an input of the transformer, and the first matching circuit is configured to transform an impedance at the input of the transformer into a first predefined impedance at the output of the first transistor.

Implementations of the circuit can include one or more of the following features. For example, the first matching circuit can include: a first inductor coupled between the output of the first transistor and ground; and a first capacitor coupled between the output of the first transistor and the transformer. The first inductor can be an adjustable inductor and the first capacitor can be an adjustable capacitor. The first inductor can have an inductance between about 0.8 nH and about 1.5 nH, and the first capacitor can have a capacitance between about 0.5 pF and about 3.5 pF.

The first matching circuit can include a second inductor coupled between the first capacitor and ground, in which the second inductor is also coupled to an input lead of the transformer. The second inductor can be an adjustable inductor. The second inductor can have an inductance between about 0.8 nH and about 1.5 nH.

In some implementations, the first predefined impedance at the output of the first transistor is between about 2 ohm and about 20 ohms. The impedance at the input of the transformer can be between about 20 ohms and 30 ohms. An output impedance of the transformer can be about 50 ohms.

In some implementations, the RF amplifier circuit includes: a second transistor; a second matching network, in which an input of the second matching circuit is coupled to an output of the second transistor, an output of the second matching circuit is coupled to the input of the transformer, the second matching circuit is configured to transform an impedance at the input of the transformer into a second predefined impedance at the output of the second transistor, and the transformer is configured to combine a signal from the first matching circuit and a signal from the second matching circuit into an output signal.

The second matching circuit can include: a first inductor coupled between the output of the second transistor and ground; and a first capacitor coupled between the output of the second transistor and the transformer. The first inductor can have an inductance between about 0.8 nH and about 1.5 nH, and the first capacitor can have a capacitance between about 0.5 pF and about 3.5 pF. The second matching circuit can include a second inductor coupled between the first capacitor and ground, in which the second inductor is also coupled to an input lead of the transformer. The second inductor can have an inductance between about 0.8 nH and about 1.5 nH.

In general, in some other aspects, the subject matter of the present disclosure can be embodied in a RF transceiver circuit that includes: a processor; modulation circuitry coupled to an output of the processor; a push-pull amplifier circuit coupled to an output of the modulation circuitry; and an antenna, in which the push-pull amplifier circuit includes a first transformer arranged to receive a signal from the output of the modulation circuitry, a first arm coupled to an output of the first transformer, in which the first arm includes a first transistor and a first matching network coupled to the first transistor, a second arm coupled to the output of the first transformer, in which the second arm includes a second transistor and a second matching network coupled to the second transistor, and a second transformer having an input coupled to both the first matching network and the second matching network, in which the second transformer is configured to combine a signal from the first matching network and a signal from the second matching network into an output signal at an output of the second transformer, and the output of the second transformer is coupled to the antenna.

In general, in some other aspects, the subject matter of the present disclosure can be embodied in a method of tuning a load of a radio-frequency (RF) push-pull amplifier circuit including a first transistor and a transformer, the method including: providing an adjustable matching network between the first transistor and the transformer, in which the adjustable matching network includes at least one adjustable inductor and at least one adjustable capacitor; obtaining an impedance at the output of the first transistor; and adjusting an impedance matching of the adjustable matching network so as to obtain a predefined impedance at the output of the first transistor.

Implementations of the method can include one or more of the following features. For example, in some implementations, adjusting the impedance matching of the adjustable matching network includes: adjusting an inductance of a first adjustable inductor of the adjustable matching network; and adjusting a capacitance of a first adjustable capacitor of the adjustable matching network. The inductance of the first adjustable inductor can be varied between about 0.8 nH and about 1.5 nH, and wherein the capacitance of the first adjustable capacitor can be varied between about 0.5 pF and about 3.5 pF. Adjusting the impedance matching of the adjustable matching network can include adjusting an inductance of a second adjustable inductor of the adjustable matching network. The inductance of the second adjustable inductor can be varied between about 0.8 nH and about 1.5 nH. The predefined impedance at the output of the first transistor can be between about 2 ohm and about 20 ohms.

The subject matter described in this specification can be implemented in particular embodiments or implementations to realize one or more of the following advantages. For example, in some implementations, the solutions for designing RF front end circuitry presented herein help reduce the guesswork and time involved in circuit design. By incorporating the tunable matching network directly into the push pull topology, designers can directly tune the circuit design, rather than go through an iterative and cumbersome process of circuit design, fabrication, and testing. In some implementations, the use of a matching network having high Q provides DC supply to an amplification device, while also transforming the load from an intermediary impedance to a final impedance. The high Q matching network can be implemented on chip using high Q wirebond technology, without requiring substantial additional laminate space on the circuit board.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a schematic diagram of an example of a wireless communication system.

FIG. 2 is a block diagram of example details of a wireless device.

FIG. 3A is a schematic diagram that illustrates an example of an RF front end circuit.

FIG. 3B is a schematic diagram that illustrates an example of an RF front end circuit.

FIG. 4 is a schematic diagram that illustrates an example of an RF front end circuit having a tunable matching network.

FIG. 5 is a Smith chart for the example RF front end circuit of FIG. 4.

### DETAILED DESCRIPTION

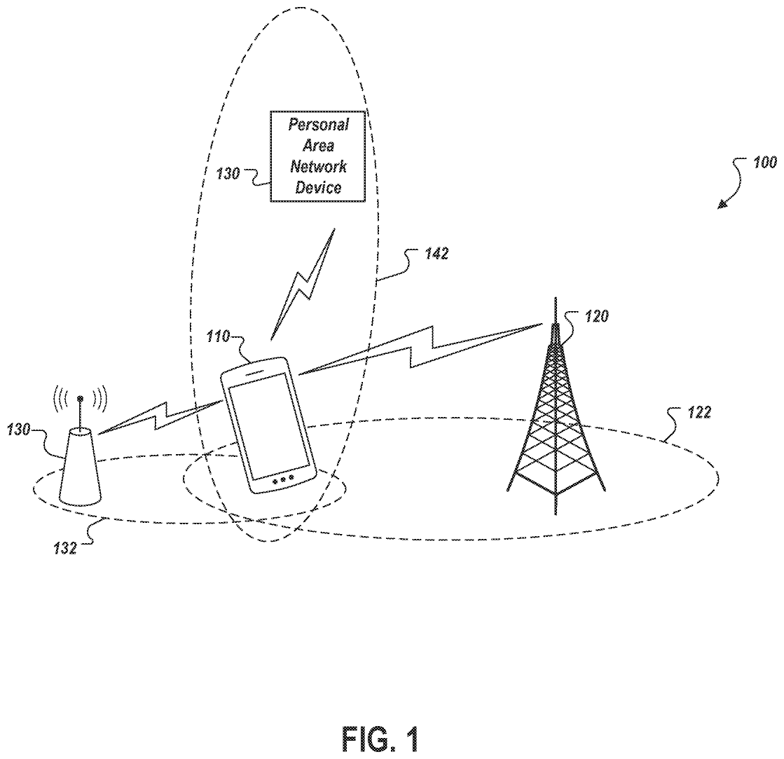

FIG. 1 is a schematic diagram of an example wireless communication system 100 including a wireless device 110 capable of communicating with one or more wireless communication networks. The one or more wireless communication networks with which the wireless device 110 is capable of communicating can include but is not limited to one or more cellular or wireless wide area networks (WWANs), one or more wireless local area networks (WLANs), one or more wireless personal area networks (WPANs), or a combination thereof.

In the example of FIG. 1, the wireless device 110 is communicating with at least one WWAN by way of at least one base station 120 and at least one WLAN by way of at least one access point 130. The at least one base station 120 can support bi-directional communication with wireless devices that are within its corresponding area of coverage 122. Similarly, the at least one access point 130 can support bi-directional communication with wireless devices that are within its corresponding area of coverage 132.

In some implementations, the at least one WWAN with which the at least one base station 120 is associated can be a fifth generation (5G) network among other generations and types of networks. In these implementations, the at least one base station 120 can be a 5G base station that employs orthogonal frequency-division multiplexing (OFDM) and/or non-OFDM and a transmission time interval (TTI) shorter than 1 ms (e.g. 100 or 200 microseconds), to communicate with wireless devices, such as wireless device 110. For example, the at least one base station 120 can take the form of one of several devices, such as a base transceiver station (BTS), a Node-B (NodeB), an evolved NodeB (eNB), a next (fifth) generation (5G) NodeB (gNB), a Home NodeB, a Home eNodeB, a site controller, an access point, a wireless router, a server, router, switch, or other processing entity with a wired or wireless network.

System 100 can use multiple channel access functionality, including for example schemes in which the at least one base station 120 and the wireless device 110 are configured to implement the Long Term Evolution wireless communication standard (LTE), LTE Advanced (LTE-A), and/or LTE Multimedia Broadcast Multicast Service (MBMS). In other implementations, the at least one base stations 120 and wireless device 110 are configured to implement UMTS, HSPA, or HSPA+ standards and protocols. Of course, other multiple access schemes and wireless protocols can be utilized. In some examples, one or more such access schemes and wireless protocols can correspond to standards that impose RF power amplifier linearity requirements.

In addition, and as shown in FIG. 1, wireless device 110 is configured to communicate with one or more personal area network (PAN) devices/systems 130 (e.g., Bluetooth® or radio frequency identification (RFID) systems and devices) over one or more WPANs. The one or more PAN devices/systems 130 can support either one-way or bi-directional communication with wireless devices that are within its corresponding area of coverage 142.

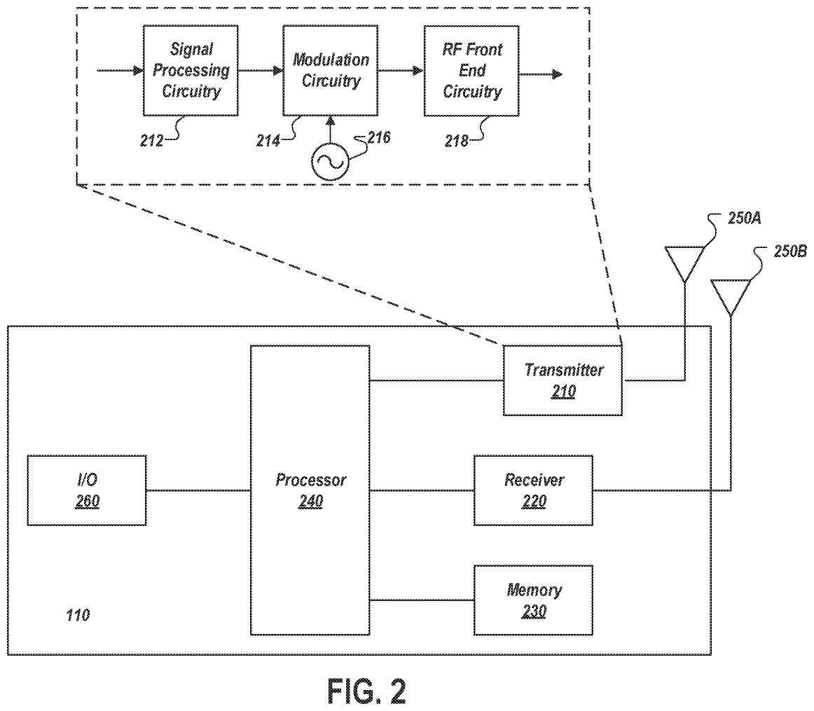

To communicate with one or both of the at least one base station 120 and the access point 130, the wireless device 110 can include singular or multiple transmitter and receiver components similar or equivalent to one or more of those described in further detail below with reference to FIG. 2 to support multiple communications with different types of access points, base stations, and other wireless communication devices.

Although FIG. 1 illustrates one example of a communication system, various changes can be made to FIG. 1. For example, the communication system 100 could include any number of wireless devices, base stations, access points, networks, or other components in any suitable configuration.

FIG. 2 is a block diagram that illustrates example details of the wireless device 110 that can implement the subject matter according to this disclosure. The wireless device 110 can, for example, be a mobile telephone, but can be other devices in further examples such as a desktop computer, laptop computer, tablet, hand-held computing device, automobile computing device and/or other computing devices. As shown in the figure, the wireless device 110 is shown as including at least one transmitter 210, at least one receiver 220, memory 230, at least one processor 240, and at least one input/output device 260. Here, only one transmitter and only one receiver are shown, but in many embodiments, multiple transmitters and receivers are included to support multiple communications of different types at the same time. Each transmitter may employ the innovations of the present disclosure.

The processor 240 can implement various processing operations of the wireless device 110. For example, the processor 240 can perform signal generation, signal coding, signal analysis, data processing, power control, input/output processing, or any other functionality enabling the wireless device 110 to operate in a communication system, such as system 100 (FIG. 1). The processor 240 can include any suitable processing or computing device configured to perform one or more operations. For example, the processor 240 can include a microprocessor, microcontroller, digital signal processor, field programmable gate array, or application specific integrated circuit, or a combination of these devices.

The transmitter 210 can be configured to modulate data or other content, filter and amplify outgoing radio frequency (RF) signals for transmission by at least one antenna 250A. In some implementations, the transmitter 210 can also be configured to amplify, filter and upconvert baseband or intermediate frequency signals to radio frequency (RF) signals before such signals are provided to the antenna 250A for transmission. The transmitter 210 can include any suitable structure for generating RF signals for wireless transmission. Additional aspects of the transmitter 210 are described in further detail below with reference to components 212-218 as depicted in FIG. 2.

The receiver 220 can be configured to demodulate data or other content received in incoming RF signals by at least one antenna 250B. In some implementations, the receiver 220 can also be configured to amplify, filter and frequency down convert RF signals received via the antenna 250B either to intermediate frequency (IF) or baseband frequency signals prior to conversion to digital form and processing. The receiver 220 can include any suitable structure for processing signals received wirelessly.

Each of the antennas 250A and 250B can include any suitable structure for transmitting and/or receiving wireless RF signals. In some implementations, the antennas 250A and 250B can be implemented by way of a single antenna that can be used for both transmitting and receiving RF signals.

One or multiple transmitters 210, one or multiple receivers 220, and one or multiple antennas 250 could be used in the wireless device 110. For example, in one embodiment, device 110 includes at least three transmitters 210 and at least three receivers 220 for communicating via at least a personal area network such as Bluetooth®, a WiFi network such as an IEEE 802.11 based network, and a cellular network. Each transmitter 210 may employ the concepts of the present disclosure. Although shown as separate blocks or components, at least one transmitter 210 and at least one receiver 220 could be combined into a transceiver. Each transceiver may employ the concepts of the present disclosure. Accordingly, rather than showing a separate block for the transmitter 210 and a separate block for the receiver 220 in FIG. 2, a single block for a transceiver could have been shown.

The wireless device 110 further includes one or more input/output devices 260. The input/output devices 260 facilitate interaction with a user. Each input/output device 260 includes any suitable structure for providing information to or receiving information from a user, such as a speaker, microphone, keypad, keyboard, display, and/or touch screen.

In addition, the wireless device 110 includes at least one memory 230. The memory 230 stores instructions and data used, generated, and/or collected by the wireless device 110. For example, the memory 230 could store software or firmware instructions executed by the processor(s) 240 and data used to reduce or eliminate interference in incoming signals. Each memory 230 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, and the like.

In some implementations, the transmitter 210 can include signal processing circuitry 212, modulation circuitry 214, and RF front end circuitry 217. The signal processing circuitry 212 may include one or more circuits that are configured to process signals received as input (e.g. from processor 240). For example, the signal processing circuitry 212 may include a digital-to-analog converter (D/A), which converts a digital input (e.g. a digital signal from processor 240) into an analog signal, which is then provided to a low pass filter, which filters the analog signal and provides the filtered analog signal to the modulation circuitry 214. The modulation circuitry 214, in addition to receiving the filtered analog signal from the signal processing circuitry 212, can, in some implementations, also receive a signal from a local oscillator 216 for modulating or adjusting the frequency of the analog signal, e.g., from a first frequency to a second frequency that is higher than the first frequency. For instance, the modulation circuitry 214 can include a mixer that frequency up-converts the filtered analog signal from a relatively low frequency (e.g. baseband frequency, or an intermediate frequency (IF) that is offset from the baseband frequency) to a relatively high frequency RF signal. Thus, a signal from the local oscillator 216 is used as a carrier signal in transmitter 210. Moreover, as shown in FIG. 2, transmitter 210 includes RF front end circuitry 217, which can include, e.g., amplification and filtering circuits that amplify and filter, respectively, the RF signal. The RF front end circuitry can also include a power amplifier that is configured to provide sufficient amplification of the signal to meet transmission requirements, as may be specified by wireless communication standards. Examples of such standards include those set forth by the 3rd Generation Partnership Project (3GPP), which is a group that unites seven telecommunications standard development organizations (ARIB, ATIS, CCSA, ETSI, TSDSI, TTA, TTC) and that develops standards for cellular telecommunications technologies, including radio access, core network and service capabilities, which provide a complete system description for mobile telecommunications.

The RF signal amplified by the power amplifier may be filtered again by at least one additional filter downstream of the power amplifier before being provided as an output of the transmitter 210 to the at least one antenna 250A for wireless transmission. Such filter or filters can alternatively be provided upstream from the power amplifier in which case the output of the power amplifier is provided to the at least one antenna 250A for wireless transmission

For various wireless communication standards, there are strict requirements as to amplifier linearity so that signals can be faithfully amplified prior to transmission. However, increasing linearity often leads to a sacrifice in efficiency (measured, e.g., through PAE), given that higher power levels tend to result in substantial power dissipation through heat loss. Moreover, power supply design limitations often restrict the amount of power RF front end circuitry consumes during operation. To improve PAE for RF mobile amplifiers, one option is to increase the gain of the output stage as much as possible so that the number of amplification stages is reduced (e.g., from three amplifier stages to two amplifier stages). A power amplifier usually includes multiple stages, in which the output stage is the final stage of the amplifier. The other stages are typically called driver stages.

A technique for improving gain and efficiency requirements of certain wireless transmission protocols is to employ push pull amplifiers in the RF front end circuitry. A push pull amplifier is an amplifier in which an incoming signal is split, usually by a primary coil, across two separate arms, where the signal on one arm is 180 degrees out of phase with the signal on the other arm. In a simplified example, the push pull amplifier uses two bipolar junction transistors or two MOSFETs, one for each arm, where one of the transistors sources current through the load, while the other transistor sinks current from the load. After a defined period of time, the transistors switch functionality such that the transistor originally sourcing current through the load instead sinks current from the load, and the other transistor originally sinking current from the load begins to source current through the load. This process is repeated during operation of the push pull amplifier. Following amplification by the transistors, the separate arms are recombined, e.g., by a secondary coil, before being provided to an output, such as the antenna of the transceiver. The push-pull amplifier thus uses neutralization techniques to cancel undesirable device parasitic capacitances, allowing for a significant gain improvement in the output stage, which in turn improves efficiency, without reducing linearity.

While computer aided design (CAD) software can be used to provide a general model of the amplifier device, the operating conditions of the amplifier (such as device junction temperatures reaching more than 120 degrees Celsius and current consumption being over a half ampere), pose significant challenges for CAD simulation tools, such that prediction of actual amplifier performance based on nonlinear models with such software is quite difficult and inaccurate. Owing to the lack of simulation accuracy, design of RF power amplifiers typically requires a substantial amount of time in the lab testing different versions of the circuit design. For instance, design of RF front end circuitry can require weeks or months in the lab through multiple iterations of designing, fabricating, and testing different circuit designs to see which designs achieve the best improvement in amplifier performance. Such redesign can include changing the shape of the transformers used in the circuit and/or modifying the design of the printed circuit board on which the components are formed, among other modifications. Moreover, for push pull topologies, the circuit performance can be very sensitive to variation in lead inductance associated with the leads of the secondary transformer, which is another factor that complicates designing the RF front circuitry. In some implementations, a transformer includes multiple leads (e.g., 2, 4, 6, 8 or other numbers of leads) coupled in parallel at both ends of the coil, where each of the leads is combined together to form a reduced equivalent lead inductance and resistive loss, further complicating the design.

The present disclosure is directed to a solution for designing RF front end circuitry, and specifically for push pull topologies, that helps reduce the guesswork and time involved in circuit design. In particular, the present disclosure is directed to a tunable matching network for RF amplifier front end circuitry that can be combined with push pull topology. The tunable matching network allows circuit designers a simplified approach for reducing undesirable impact of lead and/or trace wire inductance to allow improvements in amplifier performance. By incorporating the tunable matching network directly into the push pull topology, designers can directly tune the circuit design, rather than go through an iterative and cumbersome process of circuit design, fabrication, and testing. Once the desired performance of the RF front end circuitry is identified following the tuning process, the particular component values of the matching network can be set and incorporated into the final circuit design.

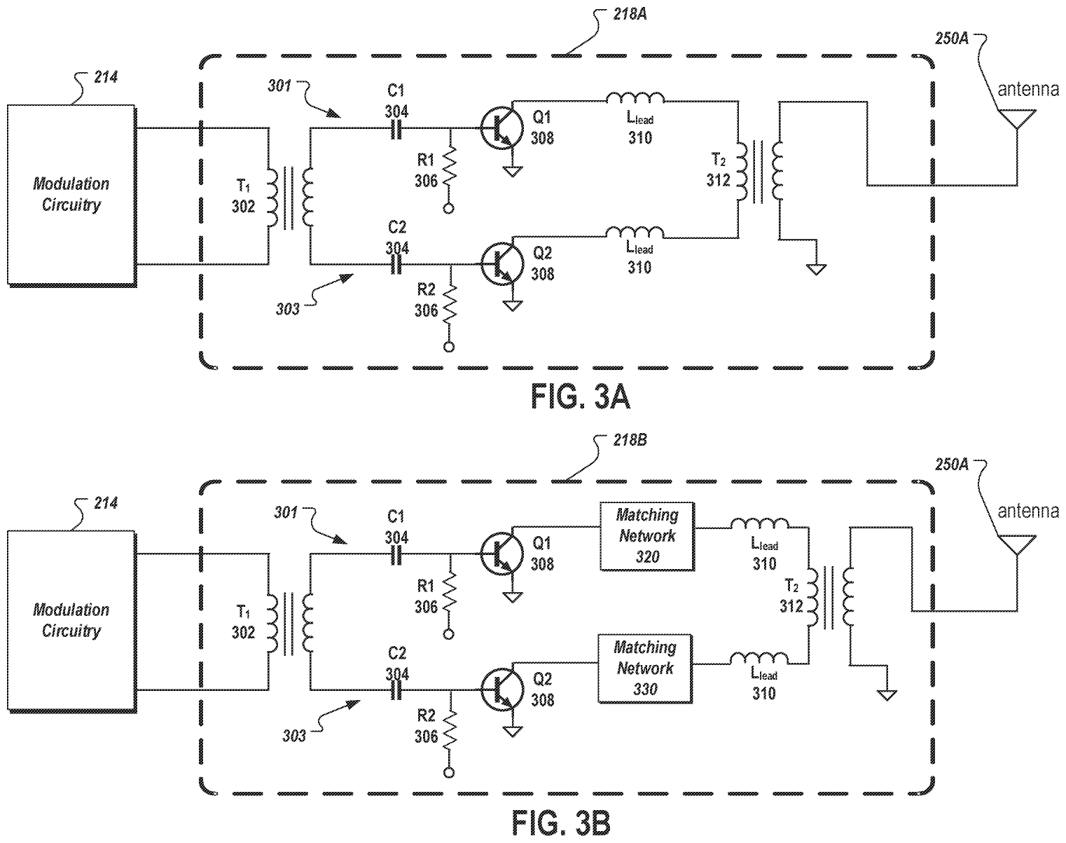

FIG. 3A is a schematic diagram that illustrates an example of a simplified RF front end circuitry 218A, such as the circuitry 218 shown in FIG. 2. The RF front end circuitry 218A includes a primary coil 302 (e.g., a first transformer) that takes an input signal and splits the input signal across two arms 301, 303. A first arm 301 includes: a first matching and biasing network that has at least one capacitor 304 (e.g., capacitor C1) and at least one resistor 306 (e.g., resistor R1); and a first transistor 308 (e.g., transistor Q1). A second arm 303 includes: a second matching and biasing network that has at least one capacitor 304 (e.g., capacitor C2) and at least one resistor 306 (e.g., resistor R2); and a second transistor 308 (e.g., transistor Q2). The signal from the primary coil 302 in the first arm 301 has a phase that is opposite to (e.g., 180 degrees out of phase from) the phase of the signal in the second arm 303. The transistors 308 in each arm serve to amplify the signal in their respective arms of the RF front end circuitry. The outputs of transistors 308 are each coupled to a secondary coil 312 (e.g., a second transformer), where the two signals are combined into an output signal that is provided to a load, such as antenna 250A. The leads (the metal trace connections) of the secondary coil 312 that are connected to the outputs of the transistors 308 contribute lead inductance 310 to the circuit to each arm 301, 303. The input signal to the RF front end circuitry 218A may be provided by, e.g., modulation circuitry 214 of the transmitter. The transistors 308 shown in FIG. 3A are depicted as bipolar junction transistors in which the outputs of the matching and biasing networks are provided as inputs to the base of the transistors. However, other transistors, such as MOSFETs may be used instead, with appropriate modification of the circuit design to accommodate the different operation of MOSFETs compared to bipolar junction transistors. Furthermore, although the matching and biasing networks in each arm are shown in FIG. 3A as having a single capacitor and a single resistor, other matching and biasing network designs are also possible. While FIG. 3A depicts a particular push pull topology, other push pull topologies are also possible.

As explained above, the performance of the push pull amplifier is very sensitive to variations in the lead inductance 310 associated with the leads of the secondary coil 312. That is, the load impedance seen by signals at the output of the transistors 308 is highly susceptible to the inductance of the transformer leads, thus complicating the circuit design. Furthermore, given the limitations of available simulation software, it is difficult to accurately design the circuitry 218A for desired performance without multiple rounds of revisions, each revision including fabrication and testing steps.

To simplify the design process and to provide a solution for addressing the variable lead inductance, a tunable matching network can be introduced into the RF front end circuitry. The tunable matching network allows a designer to adjust, during a lab testing phase, certain operating parameters of the RF front end circuitry so that the output performance exhibited by the RF front end circuitry reaches a desired performance requirement or optimal performance, with fewer iterations of circuit design, fabrication, and testing. The adjustment can include compensating for the parasitic lead inductance of the transformer coils. Once a desired operating performance (e.g., measured impedance values) is achieved, the design of the RF front end circuitry can be finalized and fabricated with a non-tunable matching network, using the values determined during the lab testing phase.

FIG. 3B is a schematic diagram that illustrates an example of an RF front end circuit 218B that includes a first matching network 320 in the first arm 301 and a second additional matching network 330 in the second arm 303 of the push pull amplifier. Each of the first and second matching networks 320, 330 are coupled to the output of the transistor in their respective arm. For instance, matching network 320 is coupled to the output (e.g., the collector) of transistor Q1, whereas matching network 330 is coupled to the output (e.g., the collector) of transistor Q2. Each matching network 320, 330 transforms the impedance seen at the input to the secondary coil 312 into a desired load impedance at the output of the amplifier (e.g., at the output of the transistors in the present example) in the matching network's respective arm. As an example, the impedance at the output of the transformer is about 50 ohms, and the impedance at the input of the transformer is between about 20 ohms and 30 ohms, e.g., about 25 ohms. The matching networks 320, 330 can be adjusted to transform the 25 ohm impedance at the input of the transformer 312 into a defined impedance at the output of the transistors 308 of between, e.g., about 2 ohms and about 20 ohms. The actual desired impedance value at the output of the amplifier may depend on predefined design parameters for the end product in which the RF front end circuitry is used. The matching networks 320, 330 can be implemented using LC matching circuit having high Q. For instance, the matching networks 320, 330 can be designed to have Q in the range of about 50 to about 100 for the operating band frequency. The capacitance and/or inductance values of the matching network can be tuned to adjust the impedance transformation achieved by the matching network.

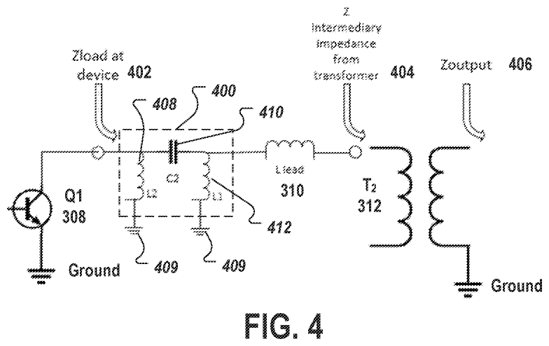

FIG. 4 is a schematic diagram that illustrates an example of a particular tunable matching network design 400 for front end RF circuitry. The matching network design 400 is just one example and other matching network designs can be used instead. The matching network 400 is shown as being applied to a single arm of a push pull topology, such as first arm 301 shown in FIG. 3B, but can included in both arms. The matching network 400 includes an LC matching circuit that is formed from at least a first inductor 408, a capacitor 410, and a second inductor 412. The first inductor 408 is coupled at one end to an output of the transistor 308. In this case, as the transistor 308 is a bipolar junction transistor (BJT), the inductor is coupled to the emitter of the transistor. In other examples, the inductor may be coupled to the collector. Alternatively, in the case the transistor is a field effect transistor, the inductor may be coupled to, e.g., the source or drain of the transistor. The other end of the first inductor 408 is coupled to RF ground 409. The second inductor 412 is coupled at a first end to an input of the secondary coil 312 (e.g., transformer). The second end of the second inductor 412 is coupled to ground. The capacitor 410 is coupled at one end to both the first end of the first inductor 408 and to the output of the transistor 308. The other end of the capacitor 410 is coupled to the first end of the second inductor 412 and to the input of the secondary coil 312, taking into account the lead inductance 310 of the secondary coil 312. As mentioned herein, the matching network 400 transforms the impedance 404 seen at the input to the secondary coil 312 (such impedance being referred to herein as the intermediary impedance) to a desired load impedance 402 at the output of the transistor 308. A similar matching network design may be used in the second arm 303 of the push pull circuit. Although the matching network 400 is shown here as including two inductors and a capacitor, other designs of the matching network 400 are also possible, with different numbers of capacitors and inductors.

The matching network 400 is tunable meaning that the inductance values and capacitance values of the network 400 can be adjusted, e.g., in the lab. That is, the inductor(s) and capacitor(s) of the tunable matching network 400 can be referred to as adjustable, variable, or lab-tunable. The inductors 408, 412 of the matching network 400 can include simple wires that are bonded to the circuit board containing the RF front end circuitry. For instance, the inductors 408, 412 can be wires that are wire bonded at one end to a RF ground plane or ground trace 409 on the printed circuit board, and bonded at another end to a signal trace that is coupled to, e.g., the input of the secondary transformer 312 and/or to, e.g., the output of the transistor 308. When the inductors 408, 412 are wires, tuning of the inductors 408, 412 can include modifying the shape and/or position of the wires on the board. For instance, the wires can be bent, pushed up, pushed down, or pushed to the side, while maintaining contact to the traces on the circuit board, to alter the inductance that is exhibited by the wires. Alternatively, or in addition, the length of the wires can be modified. Such alteration of the shape and/or height of the wire bonds can be performed using, e.g., a wire bonding machine. Laser trimming can also be used to adjust the inductance value of the inductors 408, 412. As an example, the range of values over which the inductors 408, 412 may be varied includes between about 0.8 nH to about 1.5 nH, where the accuracy of the inductance value is subject to the measurement equipment used. Other ranges are also possible.

In some implementations, the capacitor 410 can be a variable capacitor having values that can be tuned over a set range of possible values. In some implementations, the capacitor 410 can be a removable capacitor, e.g., a surface mount device, that can be soldered to and de-soldered from the printed circuit board. As an example, the range of values over which the capacitor 410 can be varied includes between about 0.5 pF to about 3.5 pF, where the accuracy of the capacitance value is subject to the measurement equipment used. Other ranges are also possible. Varying the values of the inductors 408, 412 and the capacitor 410 can allow micro-tuning of the load presented to the output of the transistor. This tuning can also compensate for the inductance of the transformer leads. For example, micro-tuning the load can include tuning approximately one to a few tenths of an ohm on both real and imaginary portions of the loading. In some implementations, the capacitor 410 can include a laser trimmable capacitor, which are built up as multilayer plate capacitors, where vaporizing the top layer with a laser decreases the capacitance by reducing the area of the top electrode.

Once a desired output load is achieved after tuning the inductor(s) and capacitor(s) matching network 400, a final design of the RF front end circuitry can be completed based on the inductance and capacitor values of the matching network. The final design using defined capacitance and inductance values obtained from tuning the matching network then can be used in mass fabrication of the RF front end circuitry. For example, in the case of a wire adjusted to a particular shape and height for a particular inductance value, the wire used for mass production can be selected to have the same shape and height. In another example, in the case of an on-chip capacitor, such as a laser-trimmable capacitor, once the desired capacitance is determined, a capacitor having that capacitance value is selected for mass production.

that includes non-variable/fixed value inductors and non-variable/fixed value capacitors.

Although the matching network described herein is shown as being used in a position at the output matching of the RF front end amplifier, such matching networks also or alternatively can be used for interstage matching as well, with additional high Q tunable LC filters. For example, in some implementations, matching networks, similar to the matching networks 320, 330 can be introduced between the modulation circuitry 214 and the primary coil 302 of the RF front end circuitry. Such matching networks can be micro-tuned in the same manner as networks 320, 330 to until a desired load transformation is obtained, after which the identified capacitance and inductance values obtained from tuning are used in a final circuit design for mass fabrication.

The process for tuning a load of an RF amplifier circuit as described above can be set forth as follows: an adjustable matching network is provided between a first transistor and a transformer of the RF amplifier circuit, in which the adjustable matching network includes at least one adjustable inductor and at least one adjustable capacitor. An impedance at the output of the first transistor is obtained by measuring the impedance value at the first transistor output. Then the matching network is adjusted through, e.g., modifying the variable inductors and capacitors of the matching network, to obtain a predefined impedance at the output of the first transistor. The matching network can include, e.g., a first adjustable inductor and a second adjustable inductor. The inductance of the adjustable inductors can be varied between about 0.8 nH and about 1.5 nH. The matching network can include, e.g., a first adjustable capacitor. The capacitance of the adjustable capacitor can be varied between about 0.5 pF and about 3.5 pF.

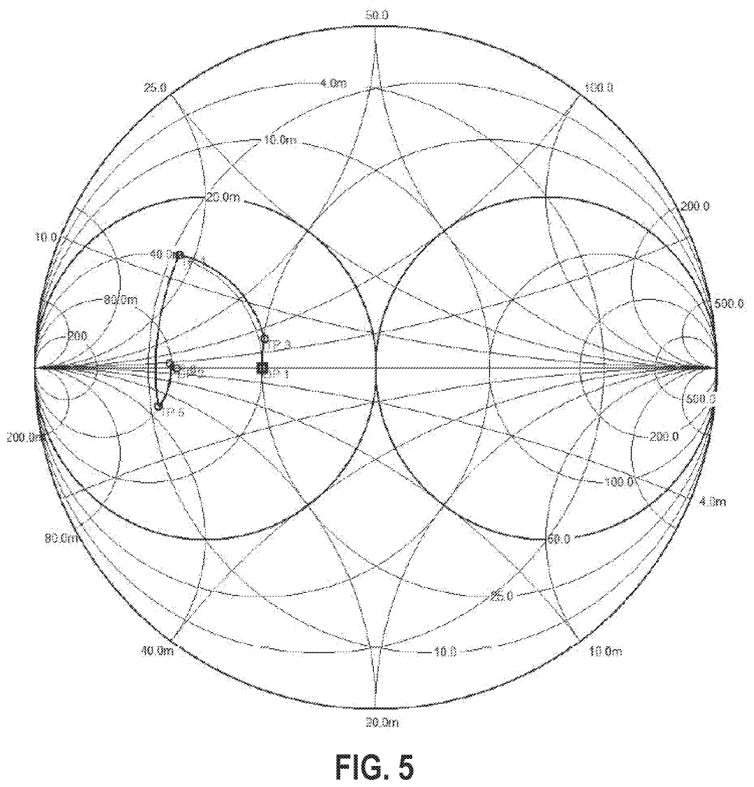

FIG. 5 is a Smith chart for the example RF front end circuit of FIG. 4 for loading conversion at 3.7 GHz. In particular, the Smith chart of FIG. 5 was calculated with the following parameters: a value of the first inductor 408 was 1.2 nH, a value of the second inductor 412 was 1.1 nH, a value of the capacitor 410 was 2.5 pF, and a value of the lead inductance 310 was 208.3 pH. In the example shown, the starting point impedance DPi is (25+j0) ohms, which excludes lead inductance 310 and impedance from the matching network 400. After factoring in 208.3 pH for the lead inductance 310, the impedance of the RF front end circuit transforms to a first intermediate impedance TP3 at (25+j4.907) ohms. As the inductance of L1 (inductor 412) is added, the impedance transforms to TP4 at (10.694+12.778) ohms. From TP4, capacitance of C2 (capacitor 410) is added to 2.5 pF, such that the impedance transforms to TP5 at (10.694−j4.175) ohms. Thus, by adding elements of the lead inductance and matching network, a trajectory for impedance transformation of the RF front end circuit can be derived graphically on the Smith chart.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system modules and components in the embodiments described above should not be understood as requiring such separation in all embodiments, and it should be understood that the described program components and systems can generally be integrated together in a single software product or packaged into multiple software products.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A radio-frequency (RF) push-pull amplifier circuit, the RF amplifier circuit comprising:
a first transistor,
a transformer; and
a first matching circuit comprising at least one capacitor and at least one inductor,
wherein an input of the first matching circuit is coupled to an output of the first transistor,
an output of the first matching circuit is coupled to an input of the transformer, and
the first matching circuit is configured to transform an impedance at the input of the transformer into a first predefined impedance at the output of the first transistor.

2. The RF amplifier circuit of claim 1, wherein the first matching circuit comprises:
a first inductor coupled between the output of the first transistor and ground; and
a first capacitor coupled between the output of the first transistor and the transformer.

3. The RF amplifier circuit of claim 2, wherein the first inductor is an adjustable inductor and the first capacitor is an adjustable capacitor.

4. The RF amplifier circuit of claim 2, wherein the first inductor is between about 0.8 nH and about 1.5 nH, and wherein the first capacitor is between about 0.5 pF and about 3.5 pF.

5. The RF amplifier circuit of claim 2, wherein the first matching circuit comprises a second inductor coupled between the first capacitor and ground, wherein the second inductor is also coupled to an input lead of the transformer.

6. The RF amplifier circuit of claim 5, wherein the second inductor is an adjustable inductor.

7. The RF amplifier circuit of claim 5, wherein the second inductor is between about 0.8 nH and about 1.5 nH.

8. The RF amplifier circuit of claim 1, wherein the first predefined impedance at the output of the first transistor is between about 2 ohm and about 20 ohms.

9. The RF amplifier circuit of claim 8, wherein the impedance at the input of the transformer is between about 20 ohms and 30 ohms.

10. The RF amplifier circuit of claim 6, wherein an output impedance of the transformer is about 50 ohms.

11. The RF amplifier circuit of claim 1, comprising:
a second transistor;
a second matching network, wherein an input of the second matching circuit is coupled to an output of the second transistor,
an output of the second matching circuit is coupled to the input of the transformer,
the second matching circuit is configured to transform an impedance at the input of the transformer into a second predefined impedance at the output of the second transistor, and
the transformer is configured to combine a signal from the first matching circuit and a signal from the second matching circuit into an output signal.

12. The RF amplifier circuit of claim 9, wherein the second matching circuit comprises:
a first inductor coupled between the output of the second transistor and ground; and
a first capacitor coupled between the output of the second transistor and the transformer.

13. The RF amplifier circuit of claim 12, wherein the first inductor is between about 0.8 nH and about 1.5 nH, and wherein the first capacitor is between about 0.5 pF and about 3.5 pF.

14. The RF amplifier circuit of claim 12, wherein the second matching circuit comprises a second inductor coupled between the first capacitor and ground, wherein the second inductor is also coupled to an input lead of the transformer.

15. The RF amplifier circuit of claim 14, wherein the second inductor is between about 0.8 nH and about 1.5 nH.

16. A radio-frequency (RF) transceiver circuit comprising:
a processor;
modulation circuitry coupled to an output of the processor;
a push-pull amplifier circuit coupled to an output of the modulation circuitry; and
an antenna,
wherein the push-pull amplifier circuit comprises
a first transformer arranged to receive a signal from the output of the modulation circuitry,
a first arm coupled to an output of the first transformer, wherein the first arm comprises a first transistor and a first matching network coupled to the first transistor,
a second arm coupled to the output of the first transformer, wherein the second arm comprises a second transistor and a second matching network coupled to the second transistor, and
a second transformer having an input coupled to both the first matching network and the second matching network, wherein the second transformer is configured to combine a signal from the first matching network and a signal from the second matching network into an output signal at an output of the second transformer, and wherein the output of the second transformer is coupled to the antenna.

17. A method of tuning a load of a radio-frequency (RF) push-pull amplifier circuit comprising a first transistor and a transformer, the method comprising:
providing an adjustable matching network between the first transistor and the transformer, wherein the adjustable matching network comprises at least one adjustable inductor and at least one adjustable capacitor;
obtaining an impedance at the output of the first transistor;
adjusting an impedance matching of the adjustable matching network so as to obtain a predefined impedance at the output of the first transistor.

18. The method of claim 17, wherein adjusting the impedance matching of the adjustable matching network comprises:
adjusting an inductance of a first adjustable inductor of the adjustable matching network; and
adjusting a capacitance of a first adjustable capacitor of the adjustable matching network.

19. The method of claim 18, wherein the inductance of the first adjustable inductor is varied between about 0.8 nH and about 1.5 nH, and wherein the capacitance of the first adjustable capacitor is varied between about 0.5 pF and about 3.5 pF.

20. The method of claim 18, wherein adjusting the impedance matching of the adjustable matching network comprises adjusting an inductance of a second adjustable inductor of the adjustable matching network.

21. The method of claim 20, wherein the inductance of the second adjustable inductor is varied between about 0.8 nH and about 1.5 nH.

22. The method of claim 17, wherein the predefined impedance at the output of the first transistor is between about 2 ohm and about 20 ohms.
